(19) United States
(12) Patent Application Publication
(10) Pub. No.: US 2019/0331317 A1
(43) Pub. Date: Oct. 31, 2019

(54) LED LENS ASSEMBLY

(71) Applicant: SUR-SEAL CORPORATION, Cincinnati, OH (US)

(72) Inventors: Brian KOELLING, Lawrenceburg, IN (US); Michael G. CHEN, Cincinnati, OH (US); Craig RALEIGH, Burlington, WI (US); Paul A. SCHERRER, Hebron, KY (US)

(21) Appl. No.: 16/394,196

(22) Filed: Apr. 25, 2019

Related U.S. Application Data
(60) Provisional application No. 62/663,045, filed on Apr. 26, 2018.

(51) Int. Cl. F21V 5/04; F21V 15/00; F21V 31/00; H01L 27/15; H01L 33/58; H01L 33/00

(52) U.S. Cl. CPC F21V 5/048; F21V 15/00; H01L 33/005; H01L 27/156; H01L 33/58; F21V 31/005

(57) ABSTRACT

An LED lens assembly that includes a secondary lens and a gasket molded to the secondary lens. At least one of the secondary lens and the gasket is made of a material that is curable using low temperature electromagnetic radiation.

### CROSS-REFERENCE TO RELATED APPLICATION

This application claims priority to and the benefit of pending U.S. Provisional Application No. 62/663,045 filed Apr. 26, 2018, which is incorporated by reference herein in its entirety.

### BACKGROUND

Light Emitting Diode (LED) light fixtures (alternately referred to as “LED light engines”) are becoming commonplace as utilities, governments, businesses, and individuals seek methods of decreasing energy costs. LED light fixtures have the advantage of decreased energy usage when compared to traditional light sources such as incandescent, metal halide, and high-pressure sodium light sources. Additionally, with projected lives of 100,000 hours or more, they provide the ideal replacement for applications were maintenance costs are high, such as in street lighting applications.

A typical LED light fixture includes an LED light source mounted within a fixture housing. The LED light source comprises a single LED chip or a small grouping of LED chips. A primary lens (also referred to as a “primary optic”) is often formed over and otherwise encases each LED chip to protect the LED chip from environmental damage and/or contamination. A secondary lens (also referred to as a “secondary optic”) is coupled to the housing and arranged to receive, diffuse, and direct light emitted from the LED light source. A gasket is commonly used to generate a seal between the housing and the secondary lens. Creating a sealed environment is particularly important when the fixture will be exposed to harsh environments, such when the fixture is used for outdoor street lighting. Some LED light fixtures also include a bezel that helps secure the secondary lens and the gasket to the housing.

The secondary lens, the gasket, and the bezel are collectively referred to as a “lens assembly” and are commonly made from plastics or polymers. Traditionally, the secondary lens, the gasket, and the bezel are formed as separate components that must be preassembled prior to securing the lens assembly to the housing. To reduce assembly costs and preassembly of the various component parts, lens assemblies in recent years have been fabricated as a one-piece component part. The one-piece lens assembly can be formed, for example, via injection molding, such as through an over-molding or co-molding process.

Creating a one-piece lens assembly, however, has its own challenges. For example, the secondary lens, the gasket, and the bezel are often made of different materials that exhibit different softening and curing temperatures. When it is required to cure one material at a temperature greater than the softening temperature of a second material, abnormalities and/or defects can result in the second material. For instance, when molding typical LSR, steel or other metal the mold is typically heated to an approximate range of 160° C. or 200° C. However, PMMA, Nylon, Polyester or optical material used for the secondary optics would often deform at these temperatures because temperatures of the mold are above the glass transition of the optical materials.

### BRIEF DESCRIPTION OF THE DRAWINGS

The following figures are included to illustrate certain aspects of the present disclosure, and should not be viewed as exclusive embodiments. The subject matter disclosed is capable of considerable modifications, alterations, combinations, and equivalents in form and function, without departing from the scope of this disclosure.

FIG. 1 is an isometric view of an example LED light fixture that may incorporate one or more principles of the present disclosure.

FIG. 2 is a cross-sectional side view of the LED light fixture of FIG. 1.

FIGS. 3A and 3B are isometric and exploded views, respectively, of the LED lens assembly of FIGS. 1 and 2.

FIG. 4A depicts an electrical connector operatively coupled to an LED light source.

FIG. 4B is an enlarged view of the electrical connector of FIG. 4B.

### DETAILED DESCRIPTION

The present disclosure is related to LED light fixtures and, more particularly, to LED lens assemblies used in LED light fixtures and methods of manufacturing the LED lens assemblies.

The embodiments discussed herein describe an LED lens assembly having at least a secondary lens and a gasket molded to the secondary lens. The gasket may be over-molded or co-molded to the secondary lens, and at least one of the secondary lens and the gasket is made of a material that is curable using low temperature electromagnetic radiation. In one embodiment, for example, the gasket may be made of a silicone that is curable using ultraviolet (UV) light emitted at or near room temperature. This may prove advantageous in mitigating damage to the secondary lens, which may be made of a material having glass transition temperature below the cure temperature of conventional gasket materials.

The embodiments discussed herein also describe a fluid-tight electrical connector that can be used with an LED light fixture that incorporates the LED lens assembly briefly described above. The electrical connector may be electrically coupled to an LED light source to power one or more LED chips mounted thereon. Moreover, the electrical connector may extend into the LED light fixture at a point of entry, and the point of entry may be sealed. The combination of the gasket of the LED lens assembly and the sealed point of entry effectively isolate the interior of the LED light fixture from external contamination, such as moisture, dust, and other contaminants.

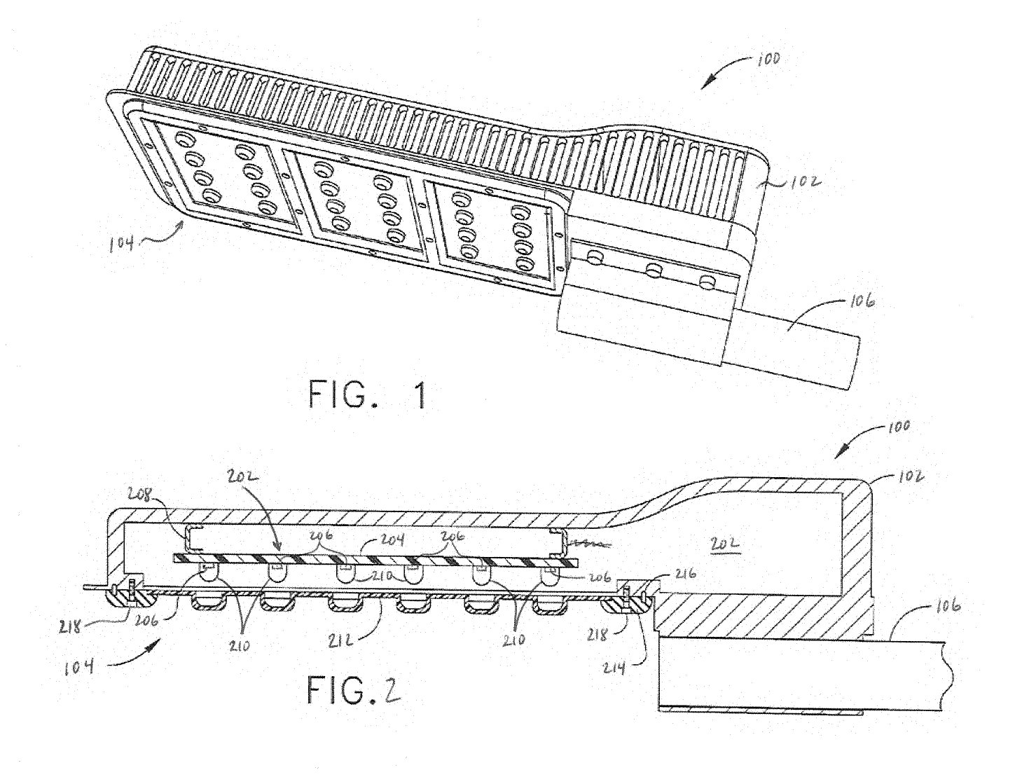

FIG. 1 is an isometric view of an example LED light fixture 100 that may incorporate one or more principles of the present disclosure. As illustrated, the LED light fixture 100 includes a housing 102, a lens assembly 104 coupled to the housing 102, and a support 104 used to support the LED light fixture 100 in a desired orientation. In operation, the LED light fixture 100 can be used as an indoor or an outdoor luminaire.

FIG. 2 is a cross-sectional side view of the LED light fixture 100. As illustrated, the housing 102 defines an interior 202 and an LED light source 202 is mounted to the housing 102 within the interior 202. The LED light source 202 may include a circuit board 204 and one or more LED chips 206 operatively coupled to the circuit board 204. The circuit board 204 may be coupled to the housing 102 with a bracket 208 or another suitable form of attachment.

Each LED chip 206 may have a primary lens 210 (alternately referred to as a “primary optic”) formed thereon or otherwise encapsulating the corresponding LED chip 206. The primary lens 210 serves to protect the corresponding LED chip 206 from environmental damage or contamination. While six LED chips 206 and corresponding primary lenses 210 are shown in FIG. 2, more or less than six may be employed, without departing from the scope of the disclosure. In at least one embodiment, for example, the several primary lenses 210 may be integrally formed as a unitary structure that is attached to the circuit board 204 as a single component part.

The lens assembly 104 may include a secondary lens 212 (alternately referred to as a “secondary optic”), a bezel 214, and a gasket 216. In the illustrated embodiment, the bezel 214 holds the secondary lens 212 and is removably coupled to the housing 102 with one or more mechanical fasteners 218. The gasket 216 interposes the bezel 214 and the housing 102 to seal the interior 202 of the housing 102. The gasket 216 may prove vital in preventing contamination of the interior 202, such as by preventing the ingress of moisture and dust. In other embodiments, the gasket 216 may instead directly interpose the secondary lens 212 and the housing 102. In such embodiments, the bezel 214 may be omitted and the mechanical fasteners 218 may instead be configured to extend through and secure the secondary lens 212 to the housing 102.

As illustrated, the secondary lens 212 is offset from the LED light source 202. The space and distance separating the secondary lens 212 and the LED light source 202 allows full distribution of the light emitted from the LED chips 206 to the secondary lens 212. More specifically, the secondary lens 212 is arranged relative to the LED light source 202 and designed to direct the light produced by the LED chip(s) 206 to an area where the light is needed, and otherwise away from areas where it is not needed or might otherwise cause light trespass. Light trespass occurs when light spills into areas where it is not wanted. For example, commercial developments in residential areas often design outdoor lighting systems to prevent light from spilling or “trespassing” onto neighboring residential properties. In operation, the secondary lens 212 may be designed to create a very intense, but small light pattern, to create a broad and diffused light pattern, to truncate the light to prevent light trespass, or to achieve any combination of those objectives.

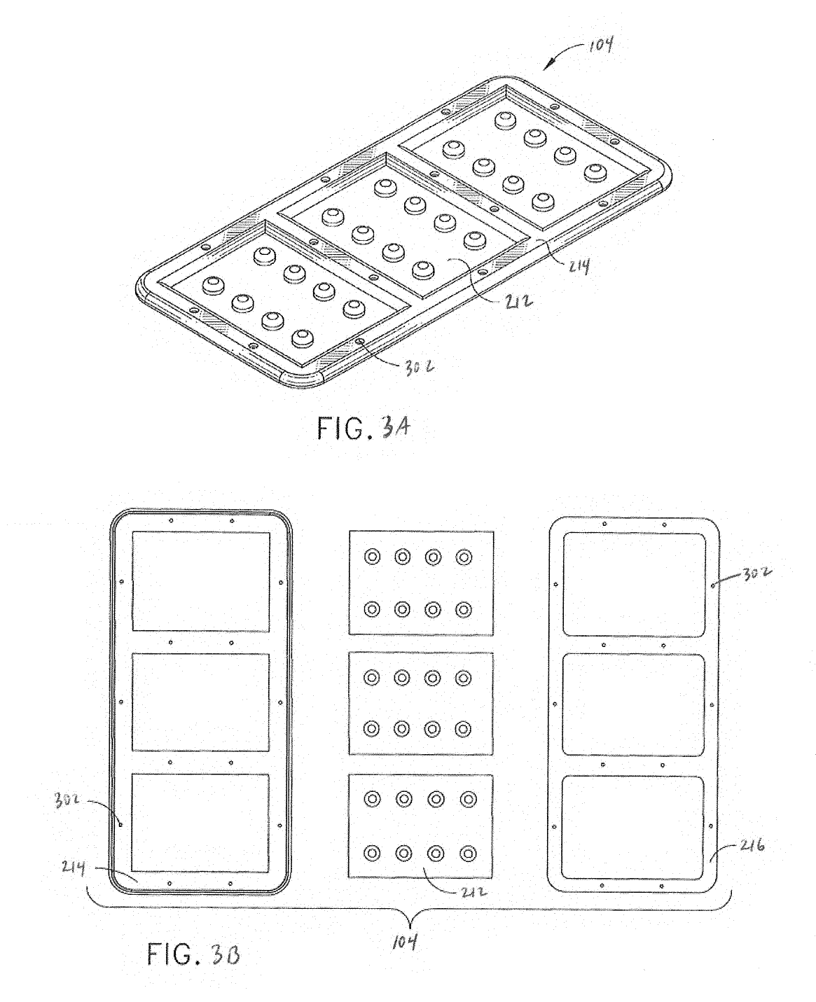

FIGS. 3A and 3B are isometric and exploded views, respectively, of the LED lens assembly 104, according to one or more embodiments. As illustrated, a plurality of fastener holes 302 may be defined in one or both of the bezel 214 and the gasket 216 for receiving the mechanical fasteners 218 (FIG. 2) used to secure the LED lens assembly 104 to the housing 102 (FIGS. 1 and 2). As mentioned above, however, in at least one embodiment the bezel 214 may be omitted from the LED lens assembly 104. In such embodiments, the gasket 216 may be sized and otherwise configured to secure the secondary lens 212 to the housing 102 and simultaneously seal the interior 202 (FIG. 2). Moreover, while FIG. 3B depicts three distinct secondary lenses 212, it is contemplated herein to have more or less than three distinct secondary lenses 212, including an embodiment with a single secondary lens 212, without departing from the scope of the disclosure.

The bezel 214 may be made of a metal, a hard plastic, or any other material that is sufficiently rigid to secure the secondary lens 212 to the housing 102 (FIGS. 1 and 2). In applications where the bezel 214 is made of a metal, the bezel 214 may be stamped from sheet metal in a die. Suitable metals for the bezel 214 include, but are not limited to, aluminum, stainless steel, copper, brass, or any combination thereof. In applications where the bezel 214 is made of a plastic, the bezel 214 may be injection molded. Suitable plastics for the bezel 214 include, but are not limited to, an acrylic, a polycarbonate, a silicone, or another suitable polymer or thermoplastic.

The secondary lens 212 may be made of an optical (i.e., including but not limited to transparent or translucent) material that is injection molded. Suitable optical materials for the secondary lens 212 include, but are not limited to, an acrylic (for example, acrylate polymer(such as poly(methyl methacrylate), alicyclic acrylate), a polycarbonate, a polystyrene, cyclic olefins, liquid silicone rubber (LSR), a polyester, polyetherimide, NAS (styrene acrylic copolymer), SAN (styrene acrylonitrile), glass, optical cramics, or another optical material including but not limited to thermoplastic, thermosetting (collectively organic) or inorganic materials. In at least one embodiment, however, the secondary lens 212 may be made of glass. The gasket 216 may also be injection molded and made of a silicone or another type of material capable of forming a fluid-tight seal.

In prior lens assemblies, the secondary lens 212, the bezel 214, and the gasket 216 would traditionally be made individually and subsequently assembled together for joint coupling to the housing 102 (FIGS. 1 and 2). As described herein, however, some or all of the component parts of the LED lens assembly 104 may be fabricated as a one-piece structure. As used herein with reference to the LED lens assembly 104, the term “one-piece structure” refers to two or more of the secondary lens 212, the bezel 214, and the gasket 216 forming a unitary and/or integral structure fabricated via an over-molding process or a co-molding process.

In one embodiment, for example, the secondary lens 212 and the gasket 216 may be formed as a one-piece structure via an over-molding process. In such embodiments, the secondary lens 212 may be formed in a first mold during a first injection molding process. The gasket 216 may then be molded onto the secondary lens 212 during a second injection molding process. In some cases, following the first injection molding process, the secondary lens 212 may be transferred to a second mold to undertake the second injection molding process. In other cases, however, the secondary lens 212 may remain, and a portion of the first mold may be modified to facilitate the second injection molding process. In either case, the over-molded material of the gasket 216 forms a bond with the material of the secondary lens 212 and thereby creates a one-piece structure. As will be appreciated, however, the process may be swapped (reversed), where the gasket 216 is instead formed first and the secondary lens 212 is over-molded onto the gasket 216, without departing from the scope of the disclosure.

In another embodiment, the secondary lens 212 and the gasket 216 may be formed as a one-piece structure during a co-molding process. In such embodiments, the secondary lens 212 and the gasket 216 are simultaneously formed during a single injection molding process. More specifically, the secondary lens 212 may be formed through a first injection molding shot, and the gasket 216 is subsequently formed through a second injection molding shot. This process can be facilitated with a single mold or with multiple molds and, as with the above-described over-molding process, the co-molded material of the gasket 216 forms a bond with the material of the secondary lens 212. Moreover, as will be appreciated, the co-molding process may also be swapped (reversed), where the gasket 216 is instead formed via the first shot and the secondary lens 212 is then formed on the gasket 216 via a second shot, without departing from the scope of the disclosure.

While the above discusses over-molding or co-molding the secondary lens 212 and the gasket 216 is it further contemplated herein to over-mold or co-mold the bezel 214 to one or both of the secondary lens 212 and the gasket 216. In some embodiments, for example, the bezel 214 may be over-molded to the secondary lens 212 before or after over-molding the gasket 216 to the secondary lens 212. In other embodiments, the bezel 214 may be co-molded to the secondary lens 212 before or after co-molding the gasket 216 to the secondary lens 212, without departing from the scope of the disclosure.

The above-described over-molding and co-molding processes, however, do not come without their challenges, especially where one or more of the secondary lens 212, the gasket 212, and the bezel 214 are made of different materials that exhibit differing glass transition (i.e., softening) and curing temperatures. In one example, the secondary lens 212 may be made of an acrylic that exhibits a glass transition temperature of around 200° F. (93.3° C.), and the gasket 216 may be made of a traditional platinum curable silicone that exhibits a curing temperature ranging between about 250° F. (121.1° C.) and about 450° F., and in some instances from between about 300-400° F. To properly cure the gasket 216 during an over-molding or co-molding process, the secondary lens 212 will be subjected to temperatures exceeding the glass transition temperature of acrylic, which might result in abnormalities and/or defects developing in the secondary lens 212.

According to the present disclosure, and to mitigate the adverse effects described above, at least one of the secondary lens 212 and the gasket 216 may be made of a material that is curable (catalyzed) using low temperature electromagnetic radiation. As used herein, the term “electromagnetic radiation” refers to ultraviolet (UV) light, visible light, radio waves, microwave radiation, infrared and near-infrared radiation, X-ray radiation, gamma ray radiation, or any combination thereof. As used herein, the term “low temperature electromagnetic radiation” refers to electromagnetic radiation emitted, dispersed, or otherwise absorbed at a temperature of around 185-200° F. or below. The glass transition temperature (Tg) of atactic PMMA is around 105° C. (221° F.). The Tg values of many commercial grades of PMMA range from 85 to 165° C. (185 to 329° F.); the range is wide due to the vast number of commercial compositions which are copolymers with co-monomers other than methyl methacrylate. In at least one embodiment, the low temperature electromagnetic radiation may comprise UV light transmitted or emitted at ambient (room) temperature, or typically between about 59° F. (15° C.) and about 77° F. (25° C.), but as high as approximately 100-110° F.

In one or more embodiments, the secondary lens 212 may be made of an optically clear material, such as an acrylic, a polycarbonate, liquid silicone rubber (LSR), a polyester, or glass. In contrast, the gasket 216 may be made of a material that is curable using low temperature electromagnetic radiation. Suitable materials that may be curable using low temperature electromagnetic radiation include, but are not limited to, UV curable silicone rubber, UV curable polyester, UV curable PMMA, other UV curable optical materials, and any combination thereof. In some embodiments, the material for the gasket 216 may be cured at or near room temperature upon being exposed to UV light. This may prove advantageous in mitigating any adverse effects on the secondary lens 212 that might otherwise occur with materials requiring elevated cure temperatures. Moreover, since the secondary lens 212 is optically clear or translucent, the material for the gasket 216 may be cured by passing the UV light through the secondary lens 212, if needed.

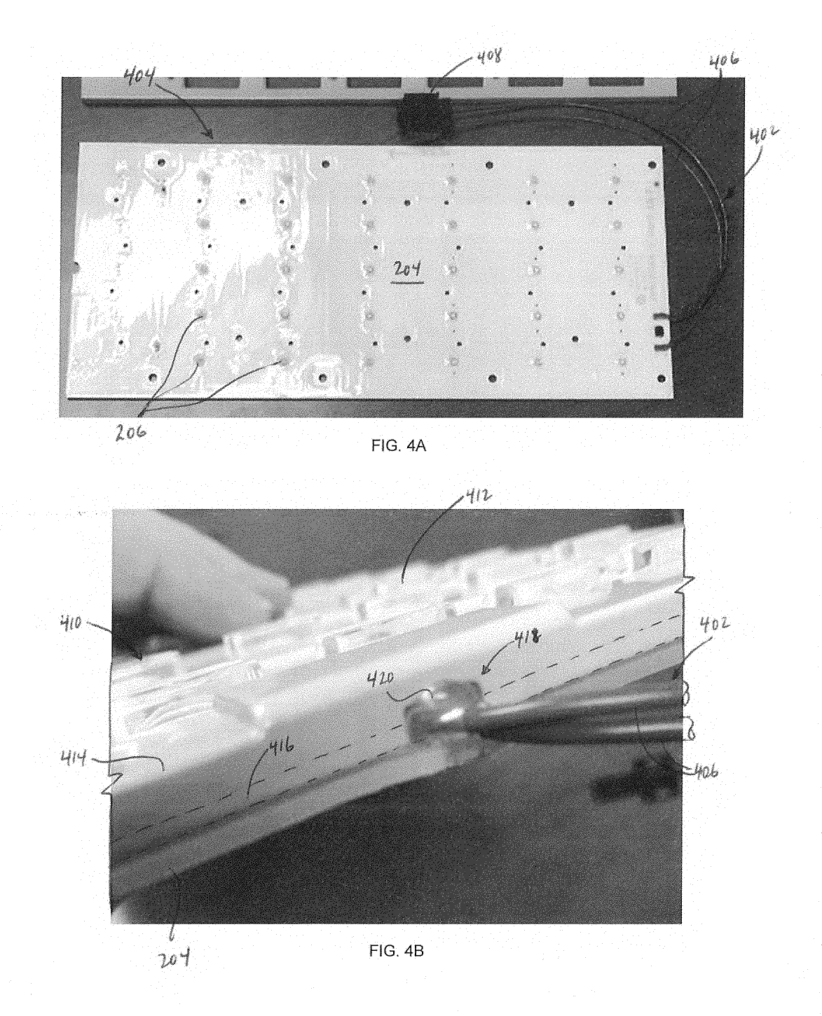

FIG. 4A depicts an example electrical connector 402 operatively coupled to a LED light source 404, according to one or more embodiments. The LED light source 404 may be similar to or the same as the LED light source 202 of FIG. 2 and may therefore be best understood with reference thereto, where like numerals represent like components not described again. As illustrated, for example, the LED light source 404 includes the circuit board 204 and a plurality of LED chips 206 mounted thereon.

The electrical connector 402 includes one or more wires 406 (two shown) electrically coupled to the circuit board 204 and configured to supply electrical power thereto to operate the LED chips 206. An adapter 408 is coupled to the distal end of the wires 406 and enables the electrical connector 402 to be electrically coupled to a source of electrical power.

FIG. 4B is an enlarged view of a portion of the electrical connector 402 entering an example LED light fixture 410, according to one or more embodiments. The LED light fixture 410 may be similar in some respects to the LED light fixture 100 of FIGS. 1 and 2. For example, as illustrated, the LED light fixture 410 may include a secondary lens 412 and a bezel 414 that secures the secondary lens to the circuit board 204. A gasket 416 (shown in dashed lines) may interpose the circuit board 204 and one or both of the secondary lens 412 and the bezel 414 to provide a sealed interface at the circuit board 204. In some embodiments, the bezel 414 may be omitted and the gasket 416 may be configured to secure the secondary lens 412 to the circuit board 204 and simultaneously provide a sealed interface.

The secondary lens 412, the bezel 414, and the gasket 416 may be the same as or similar to the secondary lens 212, the bezel 214, and the gasket 216 of FIG. 2. Accordingly, in at least one embodiment, the gasket 416 may be over-molded onto the secondary lens 412 or co-molded with the secondary lens 412, as generally described above. Moreover, the bezel 614 may be over-molded to the secondary lens 412 before or after over-molding the gasket 416 to the secondary lens 412, or alternatively co-molded to the secondary lens 412 before or after co-molding the gasket 416 thereto.

As illustrated, the wires 406 of the electrical connector 402 extend into the LED light fixture 410 at a point of entry 418. The point of entry 418 may comprise, for example, an aperture formed in a sidewall of the LED light fixture 410. In the illustrated embodiment, the point of entry 418 is defined in the bezel 414, but may otherwise comprise any opening that facilitates access into the interior of the LED light fixture 410. In some embodiments, the wires 406 extend through the gasket 416. In other embodiments, the gasket 406 is compressed over the wires 406 to form a seal thereon.

The point of entry 418 may be sealed with a seal 420 to prevent the ingress of moisture, dust, and other contaminants into the interior of the LED light fixture 410 via the point of entry 418. Accordingly, in at least one embodiment, the electrical connector 402 may be referred to as a “fluid-tight” electrical connector. The combination of the gasket 416 and the seal 420 effectively isolate the interior of the LED light fixture 410 from external contamination.

The seal 420 may be made of any material capable of providing a fluid-tight seal. In some embodiments, for example, the seal 420 may comprise room temperature vulcanizing (RTV) silicone. In other embodiments, however, the seal 420 may comprise a molded gasket or seal configured (sized) to receive the wires 406 and provide a fluid-tight seal around the wires 406 and the point of entry 412.

Therefore, the disclosed systems and methods are well adapted to attain the ends and advantages mentioned as well as those that are inherent therein. The particular embodiments disclosed above are illustrative only, as the teachings of the present disclosure may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope of the present disclosure. The systems and methods illustratively disclosed herein may suitably be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces. If there is any conflict in the usages of a word or term in this specification and one or more patent or other documents that may be incorporated herein by reference, the definitions that are consistent with this specification should be adopted.

As used herein, the phrase “at least one of” preceding a series of items, with the terms “and” or “or” to separate any of the items, modifies the list as a whole, rather than each member of the list (i.e., each item). The phrase “at least one of” allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The use of directional terms such as above, below, upper, lower, upward, downward, left, right, and the like are used in relation to the illustrative embodiments as they are depicted in the figures, the upward direction being toward the top of the corresponding figure and the downward direction being toward the bottom of the corresponding figure.

What is claimed is:

1. An LED lens assembly, comprising:
a secondary lens; and
a gasket molded to the secondary lens, wherein at least one of the secondary lens and the gasket is made of a material that is curable using low temperature electromagnetic radiation.

2. The LED lens assembly of claim 1, wherein the low temperature electromagnetic radiation comprises electromagnetic radiation below 185-200° F.

3. The LED lens assembly of claim 2, wherein the material is UV-curable silicone and the low temperature electromagnetic radiation comprises UV light.

4. The LED lens assembly of claim 1, wherein the gasket is co-molded to the secondary lens.

5. The LED lens assembly of claim 1, wherein the gasket is over-molded onto the secondary lens.

6. The LED lens assembly of claim 1, wherein the secondary lens is made of a material selected from the group consisting of glass, an acrylic, a polycarbonate, silicone rubber, polyester, and glass.

7. The LED lens assembly of claim 1, wherein the secondary lens is optically clear.

8. The LED lens assembly of claim 1, wherein the gasket is made of silicone or a thermoplastic elastomer.

9. The LED lens assembly of claim 1, further comprising a bezel coupled to the secondary lens.

10. The LED lens assembly of claim 6, wherein the bezel is one of co-molded or over-molded to the secondary lens.

11. The LED lens assembly of claim 6, wherein the bezel is made of a material selected from the group consisting of a metal, an acrylic, a polycarbonate plastic, a thermoplastic, or any combination thereof.

12. A method of fabricating an LED lens assembly, comprising:
forming a secondary lens; and
molding a gasket to the secondary lens, wherein at least one of the secondary lens and the gasket is made of a material that is curable using low temperature electromagnetic radiation.

13. The method of claim 14, wherein the low temperature electromagnetic radiation comprises electromagnetic radiation below 185-200° F., the method further comprising curing one of the secondary lens and the gasket with the low temperature electromagnetic radiation.

14. The method of claim 13, wherein the material is UV-curable silicone and the low temperature electromagnetic radiation comprises UV light, the method further comprising curing the secondary lens or the gasket with the UV light.

15. The method of claim 13, wherein molding the gasket to the secondary lens comprises co-molding the gasket to the secondary lens.

16. The method of claim 13, wherein molding the gasket to the secondary lens comprises over-molding the gasket to the secondary lens.

17. The method of claim 13, further comprising coupling a bezel to the secondary lens.

18. The method of claim 17, wherein coupling the bezel to the secondary lens comprises co-molding the bezel to the secondary lens.

19. The method of claim 17, wherein coupling the bezel to the secondary lens comprises over-molding the bezel to the secondary lens.

20. An LED light fixture, comprising:
a housing defining an interior;
an LED light source arranged within the interior and including one or more LED chips, wherein each LED chip is encapsulated by a primary lens;
a secondary lens coupled to the housing; and
a gasket molded to the secondary lens, wherein at least one of the secondary lens and the gasket is made of a material that is curable using low temperature electromagnetic radiation.

21. The LED lens assembly of claim 20, further comprising a fluid-tight connector electrically coupled to the LED light source and extending out of the housing.
